(19) United States
(12) Patent Application Publication
(10) Pub. No.: US 2009/0197416 A1
(43) Pub. Date: Aug. 6, 2009

(54) SILICON NANO WIRE HAVING A SILICON-NITRIDE SHELL AND MTHOD OF MANUFACTURING THE SAME

(75) Inventors: Eun-kyung LEE, Suwon-si (KR); Byoung-Iyong CHOI, Seoul (KR)

Correspondence Address: BUCHANAN, INGERSOLL & ROONEY PC, POST OFFICE BOX 1404, ALEXANDRIA, VA, 22313-1404, US

(73) Assignee: SAMSUNG ELECTRONICS CO., LTD., Suwon-si (KR)

(21) Appl. No.: 12/421,662

(22) Filed: Apr. 10, 2009

Related U.S. Application Data
(62) Division of application No. 11/349,250, filed on Feb. 8, 2006.

(30) Foreign Application Priority Data
Feb. 16, 2005 (KR) 10-2005-0012917

(51) Int. Cl. H01L 21/306

(52) U.S. Cl. 438/694; 438/706; 438/756; 257/E21.215; 257/E21.219

(57) ABSTRACT

Silicon nano wires having silicon nitride shells and a method of manufacturing the same are provided. Each silicon nano wire has a core portion formed of silicon, and a shell portion formed of silicon nitride surrounding the core portion. The method includes removing silicon oxide formed on the shell of the silicon nano wire and forming a silicon nitride shell.

### CROSS-REFERENCE TO RELATED PATENT APPLICATION

This application is a divisional of U.S. application Ser. No. 11/349,250 filed on Feb. 8, 2006, which claims priority of Korean Patent Application No. 10-2005-0012917, filed on Feb. 16, 2005, in the Korean Intellectual Property Office, the disclosure of which are incorporated herein in their entirety by reference.

### BACKGROUND OF THE DISCLOSURE

1. Field of the Disclosure The present disclosure relates to a silicon nano wire, and more particularly, to a silicon nano wire having a silicon-nitride shell and a method of manufacturing the same.

2. Description of the Related Art

Since the structure of carbon nano tubes was reported (S. Iijima. Nature (London) 1991, 354, 65) in 1991, further studies have investigated methods of synthesizing and using nano structures having dimensions of less than 100 nm. Nano structures are made from inorganic materials, such as single component semiconductors (Si, Ge, and B), III-V group compound semiconductors (GaN, GaAs, GaP, InP, and InAs), II-Vi group compound semiconductors (ZnS, ZnSe, CdS, and CdSe), and oxides (ZnO, MgO, and SiO₂).

Of these materials, the nano structure based on silicon has drawn the attention of many researchers as an extension of microelectronic engineering using silicon. A method of bulk synthesizing of nano wire composed of pure silicon has also been reported. This method includes a laser ablation synthesizing method (D. P. Yu et al., Solid State Commun. 105, (1998) 403.) and a high temperature evaporation synthesizing method (D. P. Yu et al., Apll. Phys. Lett. 72 (1998) 3458). Both methods grow nano wire by a vapor-liquid-solid (VLS) mechanism. Other methods can be used to grow silicon nano wire by the VLS mechanism using silicon-containing gas, such as SiCl₄, as a silicon source and Au as a catalyst.

FIG. 1A is a schematic drawing of a silicon nano wire formed by the VLS mechanism. Silicon nano wires 100 are formed by supplying vapor state silicon to an interface between a catalyst metal 40 and a silicon substrate 200, and a native oxide is formed on the surface of the silicon nano wires 100. As a result, a structure of silicon nano wires 100 having a silicon core part 20 and a silicon oxide shell part 30 is provided.

Alternatively, the silicon nano wires 100 can be grown by a solid-liquid-solid (SLS) mechanism from the silicon substrate 200 without an additional silicon source, using a catalyst such as Ni or Fe. FIG. 1B is a schematic drawing of silicon nano wires 100 formed by the SLS mechanism. The silicon nano wires 100 are formed on the upper surfaces of catalyst metals 42, and as in FIG. 1A, a structure of silicon nano wires 100 each having the silicon core unit 20 and the silicon oxide shell part 30 is provided by forming the native oxide layer on the surfaces of the silicon nano wires 100.

The silicon nano wires 100 can be employed in various fields with the development of practical application technologies. A method of using the silicon nano wires 100 in light emitting devices has been disclosed in Japanese Patent Laid-Open No. 10-326888. The light emitting devices use a silicon nano structure for a quantum confinement effect. That is, the light emitting devices use a phenomenon that, as the size of 0 dimensional particles or one-dimensional wires decreases, a band gap increases, and at this time, short wavelength light is emitted.

Examples of light emitting devices that use the silicon nano structure are a structure in which crystal quantum dots are distributed in a silicon dioxide SiO₂ matrix, as depicted in FIG. 2A, and another recent structure in which amorphous silicon quantum dots are distributed in a silicon nitride SiN_{X} matrix, as depicted in FIG. 2B.

The former structure has a low luminescence efficiency of less than 1% due to the characteristics of crystalline silicon, and is limited to use for a photo luminescence method due to the difficulty of injecting current. On the other hand, the latter structure has a higher luminescence efficiency than the crystal quantum dots due to the characteristics of the amorphous silicon quantum dots, and can be used for an electroluminescence method since current can be injected. However, to obtain a light emitting device that emits light of various wavelengths using the above structures, the size of the silicon quantum dots in both structures must be controlled to a desired size. However, this remains difficult to achieve. Therefore, a low dimensional nano structure, the size of which can be readily controlled, is needed.

### SUMMARY OF THE DISCLOSURE

The present invention may provide a silicon nano wire structure, as a low dimensional nano structure, the size of which can be readily controlled, and which has good light emitting characteristics, and a method of manufacturing the silicon nano wire structure.

According to an aspect of the present invention, there may be provided a silicon nano wire comprising: a core part formed of silicon; and a shell part formed of silicon nitride surrounding the core part.

The core part may be formed of crystalline or amorphous silicon. However, to obtain a high band gap, the core part may be formed of amorphous silicon.

According to an aspect of the present invention, there may be provided a method of manufacturing a silicon nano wire, comprising: forming a silicon nano wire having silicon oxide shell; removing the silicon oxide shell from the silicon nano wire to leave only the core part; and forming a silicon nitride shell.

Here, the silicon oxide shell may be formed by native oxidation. When all processes are performed under a non-oxidative atmosphere, for instance in a reactor from which oxygen is removed, the silicon nitride shell can be formed right after the silicon nano wires are grown.

The operation for forming the silicon nitride shell may be performed by thermal nitridation, but the present invention is not limited thereto. To control the effective diameter of the silicon nano wires, the silicon nitride may be formed radially toward the center of the silicon nano wires.

### BRIEF DESCRIPTION OF THE DRAWINGS

The above and other features and advantages of the present invention will be described in detailed exemplary embodiments thereof with reference to the attached drawings in which:

FIG. 1A is a schematic drawing of silicon nano wires formed by a VLS mechanism;

FIG. 1B is a schematic drawing of silicon nano wires formed by a SLS mechanism;

FIG. 2A is a schematic drawing of a structure of crystal silicon quantum dots distributed in a SiO₂ matrix;

FIG. 2B is a schematic drawing of a structure of amorphous silicon quantum dots distributed in a SiN_{X} matrix;

FIG. 3 is a SEM image of a conventional silicon nano wire having a silicon oxide shell;

FIG. 4 is a schematic drawing of a silicon nano wire having a nitride silicon shell according to an embodiment of the present invention;

FIGS. 5A through 5C are cross-sectional views illustrating a method of manufacturing silicon nano wires according to an embodiment of the present invention;

FIGS. 6A through 6D are cross-sectional views illustrating a process for growing silicon nano wires by an SLS mechanism;

FIG. 7 is a SEM image of silicon nano wires grown through the processes depicted in FIGS. 6A through 6D; and

FIG. 8 is a cross-sectional view illustrating a silicon nitride shell formed by thermal nitridation.

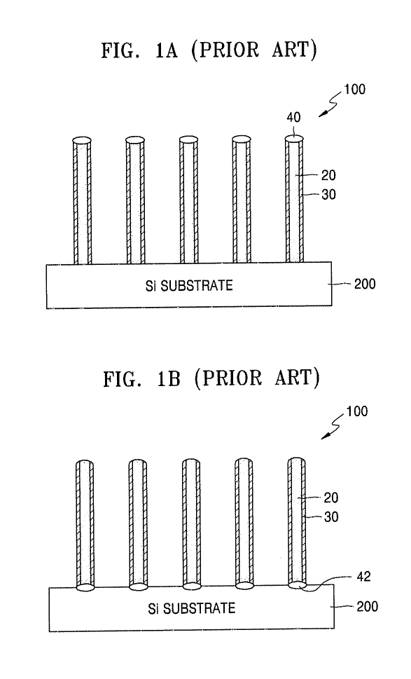

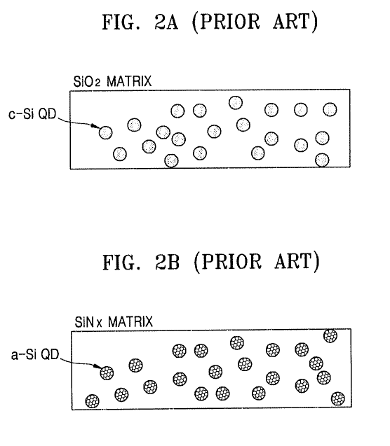

### DETAILED DESCRIPTION OF EXEMPLARY EMBODIMENTS

The present invention will now be described more fully with reference to the accompanying drawings in which exemplary embodiments of the invention are shown. Like reference numerals refer to like elements throughout the drawings.

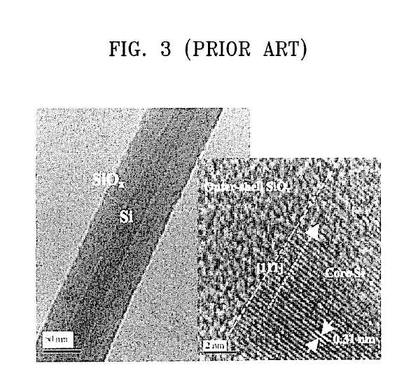

FIG. 3 is a SEM image of a conventional silicon nano wire having a silicon oxide shell. The silicon nano wire has a silicon core portion composed of crystalline silicon and a silicon oxide shell portion. The silicon oxide shell portion is generally formed by native oxidation and can also be formed by thermal oxidation. While the silicon oxide is formed at the surface of the silicon nano wire, as the silicon oxide shell portion grows, the diameter of the silicon core portion decreases, since the silicon oxide grows not only radially, but also grows toward the center of the silicon nano wire. However, the silicon oxide grows so rapidly that the diameter of the silicon nano wire using the silicon oxide shell portion cannot be controlled.

Also, many defects are present at the interface between the silicon core portion and the silicon oxide shell portion. When the silicon nano wire depicted in FIG. 3 is employed in a light emitting device, the luminescence efficiency of the light emitting device is low due to large optical losses.

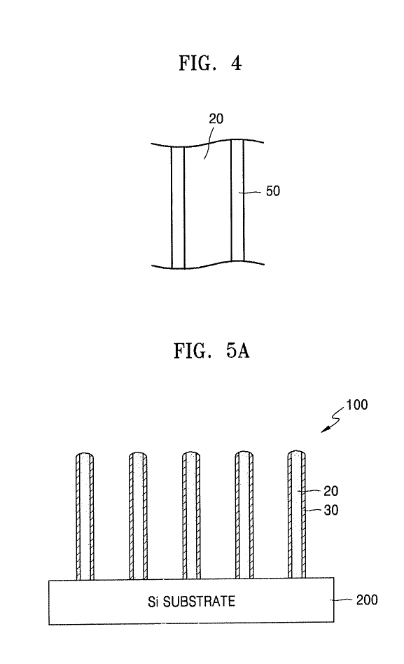

FIG. 4 is a schematic drawing of a silicon nano wire having a nitride silicon shell according to an embodiment of the present invention. The silicon nano wire according to an embodiment of the present invention includes a silicon core portion 20 that constitutes the center of a linear structure and an silicon oxide shell portion 30 that surrounds the silicon core portion 20. The diameter of the silicon nano wire including the silicon core portion 20 and the silicon oxide shell portion 30 is a few nanometers to a few tens of nanometers, and the thicknesses of the silicon core portion 20 and the silicon oxide shell portion 30 may vary as required.

The silicon core portion 20 is composed of amorphous silicon or crystalline silicon. The amorphous silicon in a bulk state has a band gap of 1.6 eV, and that of the crystalline silicon is 1.1 eV. As the effective diameter of the silicon nano wire, that is, the diameter of the silicon core portion 20 decreases, the band gap increases due to the quantum confinement effect, and at this time, the tendency of the larger band gap of the amorphous silicon is maintained rather than the band gap of the crystalline silicon. Accordingly, when the silicon nano wire according to the present invention is employed in a light emitting device, the silicon core portion 20 formed of amorphous silicon is beneficial for generating short wavelength light and injecting current.

The interface between the silicon core portion 20 and the silicon oxide shell portion 30 has fewer defects than the interface between silicon and oxide silicon. Therefore, when the silicon nano wire according to the present invention is employed in a light emitting device, optical loss is reduced and the luminescence efficiency is improved. Also, the structure of the silicon nano wire according to the present invention has a low tunneling barrier when carriers are injected, thereby the structure can easily be embodied in end use devices.

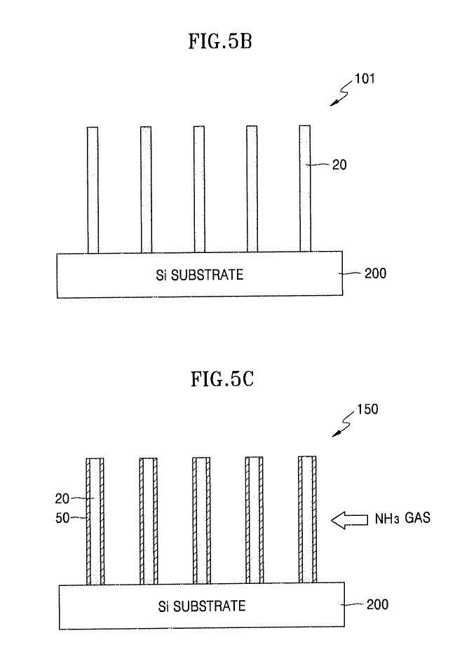

FIGS. 5A through 5C are cross-sectional views illustrating a method of manufacturing silicon nano wires according to an embodiment of the present invention. Referring to FIG. 5A, silicon nano wires 100 are formed on a silicon substrate 200. The silicon nano wires 100 have a silicon core portion 20 and a silicon oxide shell portion 30, except for the instance when the silicon nano wires are formed under a non-oxidative atmosphere. Here, the silicon oxide shell portion 30 may be a native oxide film formed during the growing process of the silicon nano wires 100 or formed afterward, or an oxide film formed by thermal oxidation.

The crystalline or amorphous silicon nano wires 100 can be grown using various methods well known in the art including a VLS mechanism and an SLS mechanism. Thus, the silicon nano wires 100 having silicon oxide shell portion 30 are provided.

Next, the silicon oxide shell portion 30 is removed from the silicon nano wires 100. The silicon oxide shell portion SiO_{X} 30 can be readily removed by wet or dry etching. When wet etching is used, the silicon oxide shell portion 30 is removed by soaking in a hydrofluoric acid (HF) solution called a buffered oxide etchant (BOE) in which HF and NH₄F are mixed at a ratio of about 1:6 to 1:7. In this case, an etching rate of approximately 800˜1000 \acute{Å}/min is shown at a temperature of 22-23° C. To reduce the etching rate, a solution of HF:NH₄F=1:10 can be used, and to further reduce the etching rate, water can be added. When dry etching is used, a plasma etching method can be used. Dry etching has an advantage of achieving more uniform etching. When the silicon oxide shell part 30 is removed, silicon nano wires 101 having only silicon core portions 20 are obtained.

Next, referring to FIG. 5C, a silicon nitride shell 50 is grown on the surface of the silicon nano wires 101. The silicon nitride shell 50 can be formed by various methods, such as thermal nitridation or deposition. However, to control the diameter of the silicon core part 20, the silicon nitride shell 50 may be grown slowly in a radial direction towards the center. As an example, in the present embodiment, the silicon nitride shell 50 is grown by a thermal nitridation method using ammonia NH₃ gas.

The thermal nitridation denotes the nitridation of a silicon surface using various nitrogen sources, such as NH₃, N₂, N, N⁺ and N2⁺ ion, NO, or plasma, and heat. In the present embodiment, the thermal nitridation method using ammonia gas is employed. The thermal nitridation method and its effect have been discussed in various publications, such as in Surf. Sci. 36 (1973) 594 by R. Heckingbottom, R. Wood, Surf. Sci. 168 (1986) 672 by A. Glachant, Phys. Rev. Lett. 60 (1988) 1049 by R. Wolkow, J. Phys. Chem. 94 (1990) 2246 by Ph. Avouris, and J. Vac. Sci. Technol. B 14 (1996) 1048 by M. Yoshimura.

The nitridation at the surface of the silicon nano wire takes place with the flowing reaction.

3Si(s)+4NH₃(g)—→Si₃N₄+6H₂O(g) Reaction 1

The silicon nitride shell 50 formed by the reaction has a slower growth rate than the silicon oxide shell grown by the thermal oxidation. Therefore, the control of the diameter of the silicon core portion 20 is carried out with ease. That is, a silicon nano wire 150 having a silicon core portion 20 with a desired diameter can be obtained since the silicon nitride shell 50 grows slowly toward the center of the silicon nano wire 150 by slowly reducing the diameter of the silicon core portion 20.

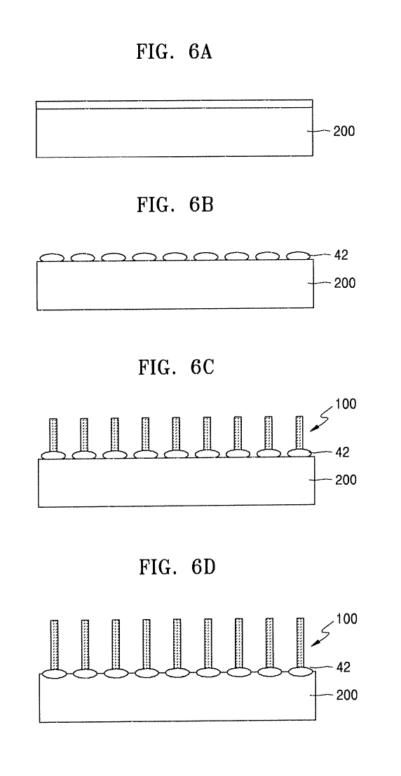

FIGS. 6A through 6D are cross-sectional views illustrating a process for growing silicon nano wires by an SLS mechanism. To manufacture a silicon nano wire having a silicon oxide shell according to an embodiment of the present invention, various methods as described above can be employed. As an example, the SLS mechanism for growing the amorphous silicon nano wire will now be described.

Referring to FIG. 6A, a Ni thin film as a catalyst metal is formed on the upper surface of a silicon substrate 200. The catalyst metal can be a transition metal, such as Ni, Fe, or Au. In the present embodiment, Ni is used as an example, but other transition metal catalysts can also be used. Next, the silicon substrate 200 is heated. Referring to FIG. 6B, when a predetermined temperature is reached, particles or tiny droplets 42 are formed. The tiny droplets 42 are a eutectic alloy of Ni and silicon. Next, referring to FIGS. 6C and 6D, silicon nano wires 100 are grown in a high temperature reactor.

To control the density of the silicon nano wires 100 on the substrate 200, the particle size of the catalyst metal can be controlled through annealing. However, the particle size of the catalyst metal can be controlled while the substrate 200 is heated by controlling the thickness of the catalyst metal thin film formed on the substrate 200, without an additional heat treatment process.

When the temperature of the substrate reaches approximately 930° C., the tiny droplets 42 of the eutectic alloy of Ni and silicon are formed. The eutectic point of the Ni-silicon alloy is approximately 993° C., but the eutectic alloy of Ni and silicon melts at 930° C. since the particles are very small and the eutectic point is lowered. If the temperature of 930 to 993° C. is maintained for a period of time, many silicon atoms diffuse into the liquid state tiny droplets 42 from the solid state substrate at the interface between the tiny droplets 42 and the substrate 200. At the opposite side of the interface of the tiny droplets 42, the silicon nano wires 100 grow, since the eutectic solution reaches a supersaturated state. At this time, if the surfaces of the tiny droplets 42 are supercooled using an inert carrier gas, such as Ar or N₂, amorphous silicon nano wires can be obtained. As described above, a light emitting device having a larger band gap can be obtained using amorphous silicon than when using crystalline silicon. Also, crystalline silicon nano wires can be obtained when an auxiliary material, such as C or WO₃ is added to the eutectic solution.

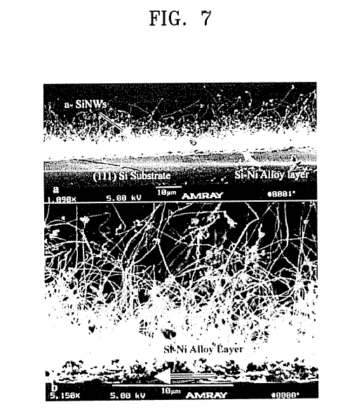

FIG. 7 is a SEM image of silicon nano wires grown through the processes depicted in FIGS. 6A through 6D. On the surfaces of the silicon nano wires grown through the processes depicted in FIGS. 6A through 6D, oxide films are formed during the growing process or after the silicon nano wires are grown. The oxide films are silicon oxide shells formed by oxygen contacting silicon, and the oxidation can be accelerated at a higher temperature. Accordingly, an operation for removing the silicon oxide is necessary except when the silicon nano wires are grown under a non-oxidative atmosphere and during an operation for forming silicon nitride shells. Therefore, the operation for removing the silicon oxide shells is necessary between the operation for forming the silicon nano wires and the operation for forming the silicon nitride shells.

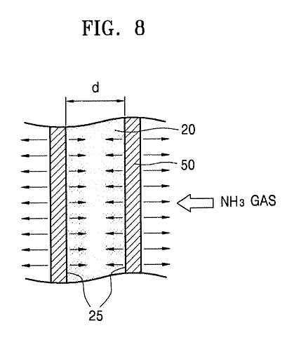

FIG. 8 is a cross-sectional view illustrating a silicon nitride shell formed by thermal nitridation. As depicted in FIG. 8, the silicon nitride shell 50 simultaneously grows both radially inwards and outwards. That is, as the silicon nitride shell 50 grows, the diameter d of the silicon core part 20 is reduced. Furthermore, the growth rate of the silicon nitride by thermal nitridation is lower than the growth rate of silicon oxide formed by thermal oxidation. Therefore, the diameter d of the silicon core part 20 is easily controlled, and silicon nano wires can be manufactured to generate light having various wavelengths using a quantum confinement effect. If the silicon core part 20 is formed of amorphous silicon, electroluminescence (EL) is also possible.

The interface 25 between the silicon core part 20 and the silicon nitride shell 50 has fewer defects than the interface between a silicon core part and a silicon oxide shell part. Accordingly, when the silicon nano wire having the silicon nitride shell 50 according to an embodiment of the present invention is utilized in a light emitting device, a relatively high luminescence efficiency can be obtained, and other optical losses can be reduced.

As described above, the present invention provides a silicon nano wire structure, as a low-dimensional nano structure, having good light emitting characteristics and an easily controlled size, and a method of manufacturing the silicon nano wire structure.

According to the present invention, silicon nano wires having silicon nitride shells are provided. The silicon nano wires having silicon cores and a desired diameter can be provided with ease by controlling the thickness of silicon nitride shell through a thermal nitridation process. Also, the silicon nano wires have good light emitting characteristics compared to conventional silicon nano wires, since there are fewer defects at the interface between silicon and silicon nitride.

The present invention also provides silicon nano wires having amorphous silicon cores to obtain a larger band gap with respect to the diameter than when using crystalline silicon cores.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A method of manufacturing a silicon nano wire, comprising:
forming a silicon nano wire having a silicon oxide shell;
removing the silicon oxide shell from the silicon nano wire to leave only a core portion; and
forming a silicon nitride shell.

2. The method of claim 1, wherein the silicon oxide shell is removed by wet etching.

3. The method of claim 1, wherein the silicon oxide shell is removed by dry etching.

4. The method of claim 1, wherein the silicon nitride shell is formed by thermal nitridation.

5. The method of claim 1, wherein the silicon nano wire having the silicon oxide shell is grown by a vapor-liquid-solid (VLS) mechanism.

6. The method of claim 1, wherein the silicon nano wire having the silicon oxide shell is grown by a solid-liquid-solid (SLS) mechanism.

7. The method of claim 6, wherein the growing of the silicon nano wire by the SLS mechanism comprises:
forming catalyst metal particles having a diameter of a few nanometers to a few tens of nanometers on a silicon substrate; and
growing the silicon nano wire on the silicon substrate by heating the substrate so the catalyst metal particles maintain a eutectic alloy state with silicon.

8. The method of claim 7, wherein the forming of the catalyst metal particles comprises:
forming a catalyst metal thin film on the silicon substrate; and
forming the catalyst metal into particles by annealing the substrate.

9. The method of claims of 7, wherein the catalyst metal is a transition metal.

10. The method of claim 1, wherein the forming of the silicon nitride shell comprises reducing the diameter of the core portion by growing the silicon nitride shell radially toward the center of the silicon nano wire.

11. The method of claim 1, wherein the forming of the silicon nitride shell comprises supplying ammonia gas around the silicon nano wire while the silicon nano wire is heated.

12. A method of manufacturing an amorphous silicon nano wire, comprising:
forming an amorphous silicon nano wire having a silicon oxide shell;
removing the silicon oxide shell from the amorphous silicon nano wire to leave only the core portion; and
forming a silicon nitride shell using thermal nitridation.

13. The method of claim 12, wherein the forming of the amorphous silicon nano wire comprises:
forming a transition metal thin film on the silicon substrate;
forming transition metal particles having a diameter of a few nanometers to a few tens of nanometers by annealing the silicon substrate; and
growing the amorphous silicon nano wire on the silicon substrate while maintaining a eutectic alloy state of the transition metal particles and silicon by heating the substrate.

14. The method of claim 13, wherein the growing of the amorphous silicon nano wire is performed by heating the silicon substrate to a temperature of 900 to 993° C.

15. The method of claim 12, wherein the forming of the silicon nitride shell comprises reducing the diameter of the silicon core portion by growing the silicon nitride shell radially toward the center of the amorphous silicon nano wire.
